(19) United States
(12) Patent Application Publication
(10) Pub. No.: US 2026/0058107 A1
(43) Pub. Date: Feb. 26, 2026

(54) SUBSTRATE PROCESSING APPARATUS AND SUBSTRATE HOLDING METHOD

(71) Applicants: THE UNIVERSITY OF TOKYO, Tokyo (JP); Tokyo Electron Limited, Tokyo (JP)

(72) Inventors: Takao OKABE, Tokyo (JP); Toshikazu AKIMOTO, Tokyo (JP); Naoki UMESHITA, Tokyo (JP); Shinichi TANABE, Tokyo (JP)

(73) Assignees: THE UNIVERSITY OF TOKYO, Tokyo (JP); Tokyo Electron Limited, Tokyo (JP)

(21) Appl. No.: 19/373,800

(22) Filed: Oct. 30, 2025

Related U.S. Application Data
(63) Continuation of application No. PCT/JP2024/016630, filed on Apr. 30, 2024.

(30) Foreign Application Priority Data
May 11, 2023 (JP) 2023-078693

(51) Int. Cl. H01J 37/32; H01L 21/683

(52) U.S. Cl. CPC H01J 37/32724; H01L 21/6833; H01J 2237/2007

(57) ABSTRACT

An electrostatic chuck is provided in a chamber, includes a placing surface for placing a substrate, and is able to electrostatically adsorb the substrate placed on the placing surface. An ionic liquid supply unit is able to supply an ionic liquid on the placing surface of the electrostatic chuck.

### CROSS-REFERENCE TO RELATED APPLICATIONS

This application is a continuation of International Application No. PCT/JP2024/016630, filed on Apr. 30, 2024, which claims the benefit of priority of the prior Japanese Patent Application No. 2023-078693, filed on May 11, 2023, the entire contents of each are incorporated herein by reference.

### FIELD

Exemplary embodiment disclosed herein relates to a substrate processing apparatus and a substrate holding method.

### BACKGROUND

Japanese Laid-open Patent Publication No. 2012-099825 discloses “a substrate supporter that is used in a reaction chamber of a plasma processing apparatus and includes a ceramic member, a metal heat transfer member that is located on the ceramic member, that has a thickness of about ¼ inch at a maximum, and that includes at least a single channel through which a liquid is circulatable to perform at least one of heating and cooling on the heat transfer member, and an electrostatic chuck that is located on the heat transfer member and includes a support surface for supporting a substrate in the reaction chamber of the plasma processing apparatus.”.

The present disclosure provides a technology for preventing occurrence of a scratch on a substrate.

### SUMMARY

In an embodiment of a present disclosure, a substrate processing apparatus includes: a chamber; an electrostatic chuck that is provided in the chamber, includes a placing surface for placing a substrate, and is able to electrostatically adsorb the substrate placed on the placing surface; and an ionic liquid supply unit that is able to supply an ionic liquid on the placing surface of the electrostatic chuck.

### BRIEF DESCRIPTION OF DRAWINGS

FIG. 1 is a diagram schematically illustrating an example of a configuration of a substrate processing apparatus according to one embodiment;

FIG. 2 is a diagram schematically illustrating an example of a state between a substrate and an electrostatic chuck according to one embodiment;

FIG. 3 is a flowchart illustrating an example of the flow of a substrate holding method according to one embodiment; and

FIG. 4 is a diagram schematically illustrating another example of the configuration of the substrate processing apparatus according to one embodiment.

### DESCRIPTION OF EMBODIMENTS

Exemplary embodiments of a substrate processing apparatus and a substrate holding method disclosed in the present application will be explained in detail below with reference to the accompanying drawings. The substrate processing apparatus and the substrate holding method disclosed below are not limited to the embodiments explained below.

Some substrate processing apparatuses are configured to adsorb a substrate, such as a semiconductor wafer, by an electrostatic chuck, supply heat-transfer gas between the electrostatic chuck and the substrate, and transfer heat between the electrostatic chuck and the substrate. However, in the configuration as described above, when the substrate moves, the substrate may rub against the electrostatic chuck and a back surface of the substrate may be damaged, so that particles may occur. In the substrate, it becomes difficult to maintain flatness of the back surface due to the damage or the particles, so that out-of-focus may occur in a subsequent exposure process of exposing the substrate.

### EMBODIMENT

### Ionic Liquid

An ionic liquid will be described below. The ionic liquid is an ionic compound that is liquid at room temperature and is also referred to as a room temperature molten salt. The ionic liquid has characteristics such that vapor pressure is approximately zero and the liquid is non-volatile (does not volatilize even in a vacuum). The ionic liquid consists of positive ions (cations) and negative ions (anions).

Examples of the positive ions contained in the ionic liquid include positive ions of a pyridinium type containing nitrogen, an imidazolium type, an ammonium type, a pyrrolidinium type, a piperidinium type, and a phosphonium type containing phosphorus. The positive ions as described above contains, as a side chain, alkyl group-(CH₂)ₙCH₃ or the like. Meanwhile, other examples of the positive ions contained in the ionic liquid include a morphonium type and a sulfonium type.

Examples of the positive ions of pyridinium type include C₂py⁺ represented by a chemical formula (C1-1) and C₄py⁺ represented by a chemical formula (C1-2), but not limited thereto.

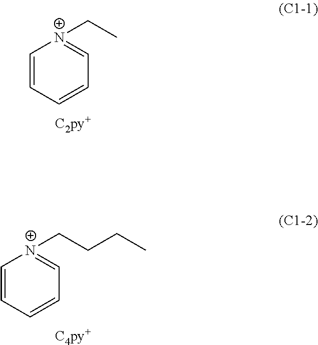

Examples of the positive ions of imidazolium type include C₂mim⁺ represented by a chemical formula (C2-1), C₄mim⁺ represented by a chemical formula (C2-2), C₆mim⁺ represented by a chemical formula (C2-3), and C₈mim⁺ represented by a chemical formula (C2-4), but not limited thereto.

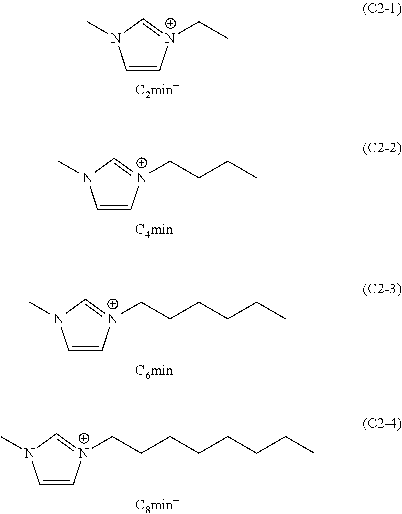

Examples of the positive ions of ammonium type include N_{3,1,1,1}⁺ represented by a chemical formula (C3-1), N_{4,1,1,1}⁺ represented by a chemical formula (C3-2), N_{6,1,1,1}⁺ represented by a chemical formula (C3-3), N_{2,2,1,(2O1)}⁺ represented by a chemical formula (C3-4), and Ch⁺ represented by a chemical formula (C3-5), but not limited thereto.

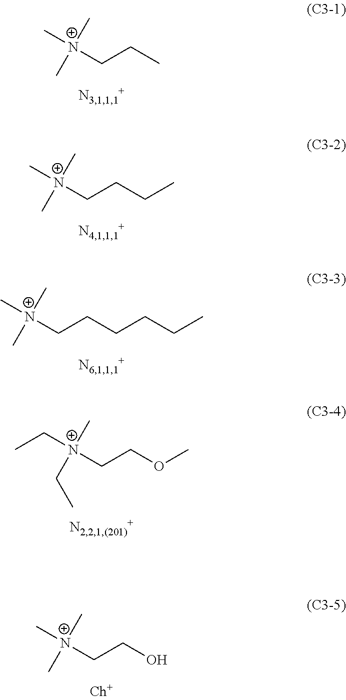

Examples of the positive ions of pyrrolidinium type include Pyr_{1,3}⁺ represented by a chemical formula (C4-1) and Pyr_{1,4}⁺ represented by a chemical formula (C4-2), but not limited thereto.

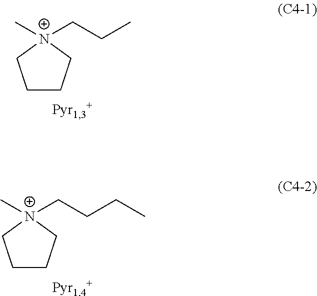

Examples of the positive ions of piperidinium type include Pip_{1,3}⁺ represented by a chemical formula (C5-1) and Pip_{1,4}⁺ represented by a chemical formula (C5-2), but not limited thereto.

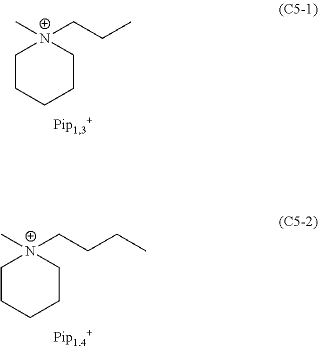

Examples of the positive ions of phosphonium type include P_{5,2,2,2}⁺ represented by a chemical formula (C6-1) and P_{6,6,6,14}⁺ represented by a chemical formula (C6-2), but not limited thereto.

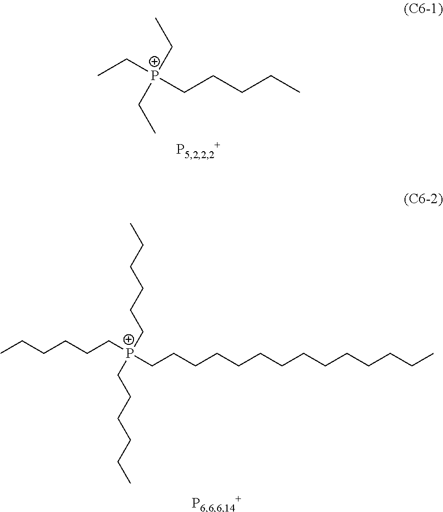 [SMILES: CCCCC[P+](CC)(CC)CC ; CCCCCCCCCCCCCC[P+](CCCCCC)(CCCCCC)CCCCCC]

Examples of the negative ions contained in the ionic liquid include TfO⁻ represented by a chemical formula (A1), Tf₂N⁻ (TFSA⁻) represented by a chemical formula (A2), Tf₃C⁻ represented by a chemical formula (A3), FSA-represented by a chemical formula (A4), CH₃COO⁻ represented by a chemical formula (A5), CF₃COO⁻ represented by a chemical formula (A6), BF₄⁻ represented by a chemical formula (A7), PF₆⁻ represented by a chemical formula (A8), (CN)₂N⁻ represented by a chemical formula (A9), AlCl₄⁻ represented by a chemical formula (A10), and Al₂Cl₇ represented by a chemical formula (A11), but not limited thereto. Meanwhile, other examples of the negative ions contained in the ionic liquid include PF₆⁻ and Cl⁻.

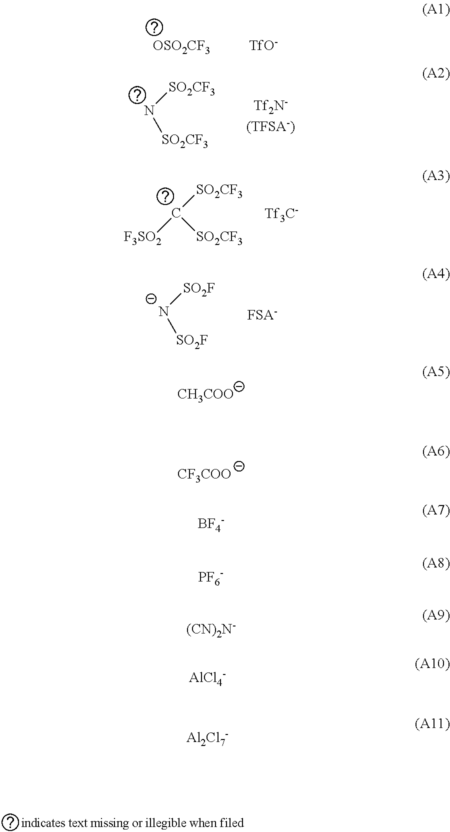

Meanwhile, specific examples of the ionic liquid include, N,N-Diethly-N-methyl-N-(2-methoxyethyl) ammonium bis(trifluoromethanesulfonyl)imide (DEME/TFSA) and 1-Ethyl-3-methylimidazolium Dicyanamide.

### Configuration of Substrate Processing Apparatus 10

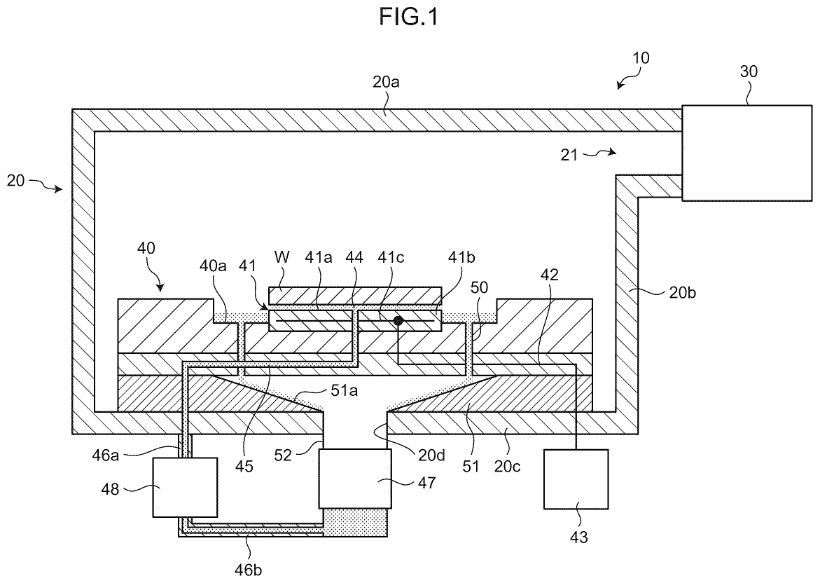

An example of a substrate processing apparatus 10 according to one embodiment will be described below. FIG. 1 is a diagram schematically illustrating an example of a configuration of the substrate processing apparatus 10 according to one embodiment. The substrate processing apparatus 10 is an apparatus that performs substrate processing, such as film formation or etching, on a substrate W, such as a semiconductor wafer. The substrate processing apparatus 10 includes a chamber 20, an exhaust mechanism 30, and a stage 40.

The chamber 20 is configured such that the interior is airtight. The chamber 20 includes a ceiling wall 20a, a bottom wall 20c, and a side wall 20b that connects the ceiling wall 20a and the bottom wall 20c.

An exhaust port 21 is formed in the side wall 20b of the chamber 20. The exhaust mechanism 30 is connected to the chamber 20 via the exhaust port 21. A vacuum pump and a pressure control valve are provided in the exhaust mechanism 30. The exhaust mechanism 30 is configured to be able to regulate pressure in the chamber 20 by controlling the vacuum pump and the pressure control valve. Examples of the vacuum pump include a dry pump and a turbo molecular pump. In this manner, the chamber 20 may regulate the pressure, and may additionally supply N₂ or the like from a gas port (not illustrated) to achieve inert atmosphere at atmospheric pressure.

In the chamber 20, the stage 40 is disposed. The stage 40 is formed in a disc shape. An electrostatic chuck 41 is provided on the stage 40. The electrostatic chuck 41 is formed to approximately the same size as the substrate W, and disposed in the center of an upper surface of the stage 40. A placing surface 41a for placing the substrate W is formed on an upper surface of the electrostatic chuck 41. The electrostatic chuck 41 is configured to be able to electrostatically adsorb the substrate W that is placed on the placing surface 41a. For example, the electrostatic chuck 41 includes a ceramic member 41b and an electrostatic electrode 41c that is disposed in the ceramic member 41b. A power supply 43 is connected to the electrostatic electrode 41c via a wire 42. The electrostatic chuck 41 electrostatically adsorbs the substrate W by application of voltage to the electrostatic electrode 41c from the power supply 43 via the wire 42. Meanwhile, the electrostatic chuck 41 may be configured such that the electrostatic electrode 41c is divided into a plurality of pieces. Further, the electrostatic chuck 41 may be of a monopolar type that applies positive voltage or negative voltage from the power supply 43 or may be a bipolar type that alternately applies positive voltage and negative voltage from the power supply 43.

The substrate processing apparatus 10 is configured to be able to supply an ionic liquid to the placing surface 41a of the electrostatic chuck 41. For example, a flow-out port 44 is formed in a central portion of the placing surface 41a of the electrostatic chuck 41. A channel 45 that communicates with the flow-out port 44 of the electrostatic chuck 41 is formed in the chamber 20 and the stage 40. A pipe 46a is connected to the channel 45. It is preferable that the ionic liquid exhibits viscosity of 120 mPa/s or less and has electrical conductivity of 2.6 mS/cm or less at 20° C., for example. The ionic liquid consists of, for example, DEME (N,N-Diethly-N-methyl-N-(2-methoxyethyl)ammonium) as positive ions and TFSA-(bis(trifluoromethanesulfonyl)imide) as negative ions. Meanwhile, the ionic liquid is not limited to this example, and may be any of those as described above.

A supply unit 47 and a temperature regulating unit 48 are provided outside the chamber 20. The ionic liquid is stored in the supply unit 47. The supply unit 47 is connected to a temperature regulating unit 48b via a pipe 46b. The supply unit 47 includes a pump and supplies the stored ionic liquid to the temperature regulating unit 48b via the pipe 46b. The temperature regulating unit 48 is configured to be able to regulate temperature of the ionic liquid. The pipe 46a is connected to the temperature regulating unit 48. The temperature regulating unit 48 regulates temperature of the ionic liquid supplied from the pipe 46b to predetermined temperature, and supplies the ionic liquid to the pipe 46a. The ionic liquid supplied to the pipe 46a flows through the pipe 46a and the channel 45, flows out of the flow-out port 44 of the electrostatic chuck 41, and is supplied to the placing surface 41a. In the configuration of the substrate processing apparatus 10 illustrated in FIG. 1, the flow-out port 44, the channel 45, the pipes 46a and 46b, and the supply unit 47 corresponds to an ionic liquid supply unit of the present disclosure.

The substrate processing apparatus 10 is configured to be able to recover the ionic liquid supplied to the placing surface 41a. For example, the stage 40 is formed to be wider than the electrostatic chuck 41, and a recess 40a is formed around the electrostatic chuck 41. The recess 40a is formed to be lower than the upper surface of the electrostatic chuck 41 and surround the electrostatic chuck 41. A plurality of channels 50 that allow communication from the recess 40a to a lower surface communicate are formed in the stage 40. The ionic liquid supplied to the placing surface 41a spreads out and flows on the placing surface 41a, and flows into the recess 40a from an outer circumference of the placing surface 41a. The ionic liquid that has flown into the recess 40a flows to the channels 50.

A recovery cup 51 is provided in a lower part of the stage 40. The recovery cup 51 is formed so as to cover the entire lower part of the stage 40. A funnel 51a in a funnel shape is formed in the recovery cup 51. The funnel 51a is shaped such that an upper inner diameter is larger than a region in which the channels 50 are provided in the bottom wall 20c and the inner diameter gradually decreases toward the lower part.

A through hole 20d is formed in the bottom wall 20c of the chamber 20. The funnel 51a communicates with the through hole 20d. The through hole 20d is connected to the supply unit 47 via a channel 52. The ionic liquid that has flown into the channels 50 flows along the funnel 51a and recovered by the supply unit 47 via the through hole 20d and the channel 52. In the configuration of the substrate processing apparatus 10 illustrated in FIG. 1, the recess 40a of the stage 40, the channels 50, the recovery cup 51, the through hole 20d, and the channel 52 corresponds to a recovery unit of the present disclosure.

The supply unit 47 supplies the recovered ionic liquid to the temperature regulating unit 48 via the pipe 46b. The temperature regulating unit 48 regulates the temperature of the ionic liquid supplied from the pipe 46b to predetermined temperature, and supplies the ionic liquid to the pipe 46a. In this manner, the ionic liquid is used in a circulating manner. The substrate processing apparatus 10, by circulating the ionic liquid as described above, is able to absorb heat of the substrate W by the ionic liquid and stabilize the temperature of the substrate W.

Operation of the substrate processing apparatus 10 will be briefly described below.

The substrate processing apparatus 10 exhausts air by the exhaust mechanism 30 and lowers internal pressure of the chamber 20 to a predetermined degree of vacuum. The substrate processing apparatus 10 supplies the ionic liquid from the supply unit 47 to the placing surface 41a. In the substrate processing apparatus 10, the substrate W that is a target of substrate processing is carried in the chamber 20 by a transfer mechanism, such as a transfer arm, via a carry-in/out port (not illustrated) and placed on the placing surface 41a. When the substrate is to be carried out from the chamber 20, the substrate W is lifted up from the placing surface 41a by a lifter pin (not illustrated) and carried out by the transfer mechanism, such as a transfer arm.

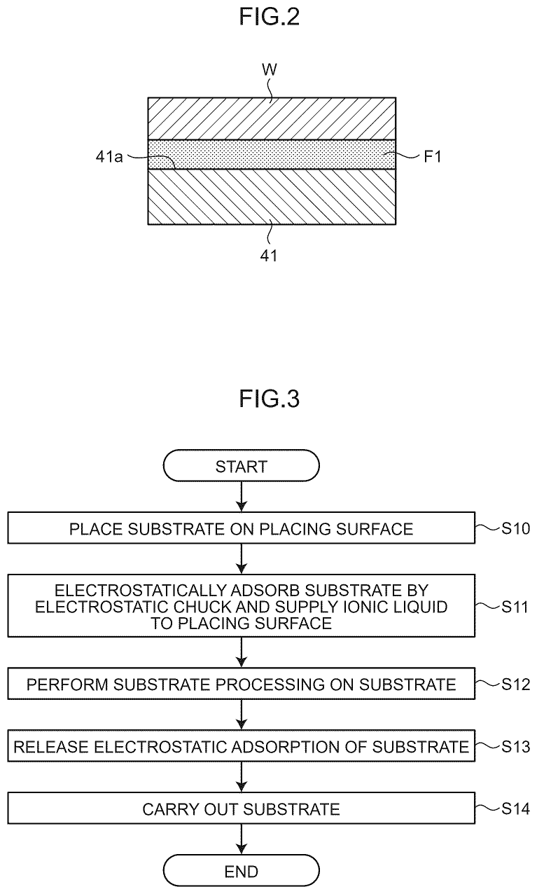

FIG. 2 is a diagram schematically illustrating an example of a state between the substrate W and the electrostatic chuck 41 according to one embodiment. By supplying the ionic liquid to the placing surface 41a of the electrostatic chuck 41, a film F1 is formed by the ionic liquid between the substrate W and the placing surface 41a. The film F1 of the ionic liquid functions as a cushion material. With the film F1 of the ionic liquid between the substrate W and the placing surface 41a, the substrate processing apparatus 10 is able to prevent contact between the placing surface 41a and the substrate W even when the substrate W moves, so that it is possible to prevent occurrence of a scratch on a back surface of the substrate W. Further, with the film F1 of the ionic liquid, the substrate processing apparatus 10 is able to efficiently transfer heat between the electrostatic chuck 41 and the substrate W. Furthermore, the substrate processing apparatus 10 circulates the ionic liquid for which the temperature is regulated by the temperature regulating unit 48, so that it is possible to control the temperature of the substrate W and the stage 40 by the ionic liquid.

Meanwhile, in some cases, in the substrate processing apparatus 10, adsorption force of the substrate W by the electrostatic chuck 41 decreases with increase in a film thickness of the film F1 of the ionic liquid, and it becomes difficult to stably hold the substrate W.

Change of the adsorption force of the substrate W and scratches that occurred on the substrate W with respect to change of the film thickness of the ionic liquid were evaluated by experiments. In the experiments, a semiconductor wafer with a diameter of 100 mm was adopted as the substrate W, the ionic liquid was coated on the back surface of the substrate W, the substrate W is subsequently placed on the placing surface 41a of the electrostatic chuck 41, and the adsorption force of the substrate W and scratches that occurred on the substrate W were evaluated. The ionic liquid consists of DEME as positive ions and TFSA⁻ as negative ions. The film thickness of the ionic liquid changed by changing an amount of coating of the ionic liquid that is coated on the back surface of the substrate W. Table 1 represents evaluation results.

TABLE 1

| Ionic Liquid | Ionic Liquid | | Adsorption | Scratch |
|---|---|---|---|---|
| Coating | Film | | Force | Prevention |
| Amount | Thickness | Voltage | Judgement | Judgement |
| [μL] | [μm] | [kV] | Result | Result |
| 0 | 0.0 | ±2 | ∘ | x |
| | | ±5 | ∘ | x |
| 10 | 1.3 | ±2 | ∘ | ∘ |
| | | ±5 | ∘ | Δ |
| 20 | 2.6 | ±2 | ∘ | ∘ |
| | | ±5 | ∘ | Δ |
| 30 | 3.8 | ±2 | x | ∘ |
| | | ±5 | x | ∘ |

An ionic liquid coating amount indicates a liquid amount of the ionic liquid that is coated on the back surface of the substrate W. An ionic liquid film thickness indicates the film thickness of the ionic liquid on the back surface of the substrate W. Meanwhile, a case in which the ionic liquid coating amount was set to 0 ml indicates a case in which the substrate W on which the ionic liquid is not coated is placed on the placing surface 41a of the electrostatic chuck 41.

Voltage indicates positive voltage and negative voltage that were alternately applied from the power supply 43 to the electrostatic electrode 41c of the electrostatic chuck 41. An adsorption force judgement result is a result of judgement on adsorption of the substrate W. In the adsorption force judgement result, “∘” indicates a case in which the adsorption force of the substrate W was equal to or larger than predetermined adsorption force with which it was possible to judge that the substrate W was stably held, and “x” indicates a case in which the adsorption force was smaller than the predetermined adsorption force. A scratch prevention judgment result is a result of judgement on scratches that occurred on the back surface of the substrate W. In the scratch prevention judgement result, “∘” indicates a case in which no scratch occurred, “Δ” indicates a case in which 1 to 4 scratches occurred, and “x” indicates a case in which 5 or more scratches occurred.

As represented by Table 1, when the ionic liquid coating amount was 10 ml, 20 ml, and 30 ml, the scratch prevention judgement result was “∘” or “Δ”. This result indicates that the ionic liquid functions as a cushion material between the substrate W and the placing surface 41a. Therefore, by supplying the ionic liquid to the placing surface 41a of the electrostatic chuck 41, it is possible to prevent occurrence of a scratch on the back surface of the substrate W.

In contrast, when the ionic liquid coating amount was 30 ml, the scratch prevention judgement result was “∘” but the adsorption force judgement result was “X”. This result indicates that it is difficult to stably adsorb the substrate Q when the film thickness of the ionic liquid is increased. To stably hold the substrate W, it is preferable to set the film thickness of the ionic liquid to 2.6 μm or less.

The substrate processing apparatus 10 according to one embodiment, by changing a supply amount of the ionic liquid that is supplied from the supply unit 47 to the pipe 46b, is able to change the film thickness of the ionic liquid on the placing surface 41a. The supply unit 47 supplies the ionic liquid so as to achieve a predetermined film thickness that allows electrostatic adsorption of the substrate on the placing surface 41a. For example, the supply unit 47 supplies the ionic liquid such that the film thickness of the ionic liquid on the placing surface 41a reaches 2.6 μm or less. As a lower limit of the film of the ionic liquid, the thinnest thickness at which the state in which the film of the ionic liquid covers the placing surface 41a can be maintained is adopted as the lower limit. The supply unit 47 supplies the ionic liquid so as to maintain a state in which the film of the ionic liquid covers the placing surface 41a. For example, a supply amount of the ionic liquid per unit time with which the film thickness of the ionic liquid covering the placing surface 41a reaches 2.6 μm or less is obtained by experiments or the like. The supply unit 47 supplies the ionic liquid to the pipe 46b at the obtained supply amount per unit time.

The substrate processing apparatus 10 is able to electrostatically adsorb the substrate W by the electrostatic chuck 41 by setting the film thickness of the ionic liquid on the placing surface 41a to 2.6 μm or less. With this configuration, the substrate processing apparatus 10 is able to prevent occurrence of a scratch on the back surface of the substrate W and stably hold the substrate W.

Furthermore, when the substrate processing apparatus 10 performs, as the substrate processing, plasma processing, such as plasma etching, there is a problem in that the substrate W generates heat. In the substrate processing apparatus 10 according to the present embodiment, the ionic liquid in contact with the substrate W absorbs heat, so that it is possible to stabilize the temperature of the substrate W.

Moreover, the film thickness of the ionic liquid in the lower part of the substrate W needs to be a thin film thickness at which the substrate W can be electrostatically adsorbed. In contrast, to absorb the heat by the ionic liquid on the substrate W, it is preferable to increase the film thickness of the ionic liquid in the lower part of the substrate W. In other words, the film thickness of the ionic liquid on the placing surface 41a and heat capacity of the ionic liquid have a trade-off relationship. The substrate processing apparatus 10 according to the present embodiment circulates the ionic liquid, so that the entire ionic liquid can ensure heat capacity enough to absorb the heat of the substrate W in processing. Furthermore, the substrate processing apparatus 10 according to the present embodiment ensures a thin film thickness at which the substrate W can be electrostatically adsorbed, so that it is possible to stabilize the temperature of the substrate W in processing while electrostatically adsorbing the substrate W.

### Flow of Substrate Processing

A flow of the substrate processing including the substrate holding method of the present disclosure will be described below. FIG. 3 is a flowchart illustrating an example of the flow of the substrate processing according to one embodiment.

The substrate W is carried in the chamber 20 by the transfer mechanism, such as a transfer arm, via the carry-in/out port (not illustrated) and placed on the placing surface 41a (Step S10).

The substrate processing apparatus 10 applies voltage from the power supply 43 to the electrostatic electrode 41c to electrostatically adsorb the substrate W placed on the placing surface 41a by the electrostatic chuck 41, and supplies the ionic liquid from the supply unit 47 to the placing surface 41a to hold the substrate W (Step S11).

The substrate processing apparatus 10 performs the substrate processing on the substrate W held by the electrostatic chuck 41 (Step S12).

When the substrate processing on the substrate W is terminated, the substrate processing apparatus 10 stops application of the voltage from the power supply 43 and releases electrostatic adsorption of the substrate W (Step S13).

The substrate W placed on the placing surface 41a is carried out from the chamber 20 by the transfer mechanism, such as a transfer arm, via the carry-in/out port (not illustrated) (Step S14).

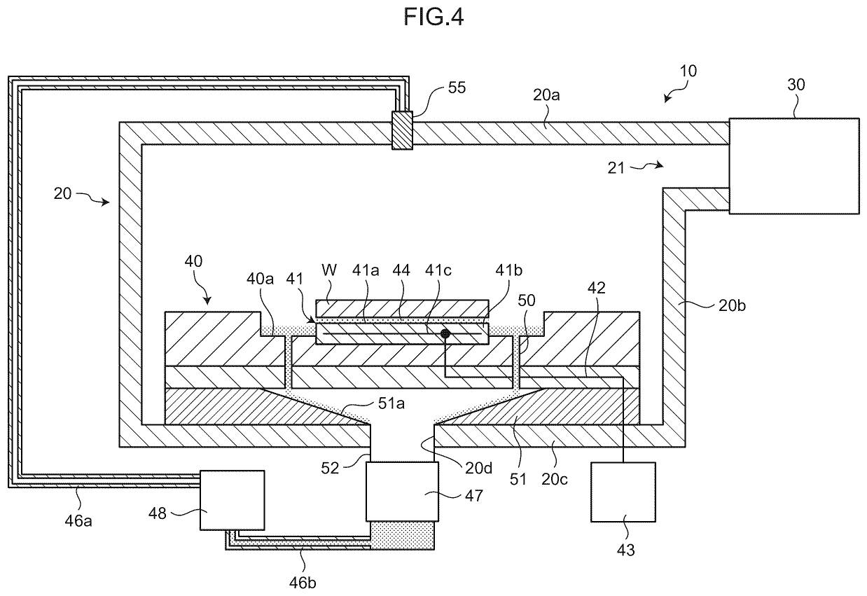

Meanwhile, in one embodiment as described above, the example has been described in which the ionic liquid is supplied from the flow-out port 44 formed in the electrostatic chuck 41 to the surface of the electrostatic chuck 41. However, the disclosed technology is not limited to this example. For example, it may be possible to drop the ionic liquid from above the electrostatic chuck 41 to supply the ionic liquid to the surface of the electrostatic chuck 41. FIG. 4 is a diagram schematically illustrating another example of the configuration of the substrate processing apparatus 10 according to one embodiment. A nozzle 55 is provided at a position above the placing surface 41a of the electrostatic chuck 41 in the chamber 20. The pipe 46a is connected to the nozzle 55. The supply unit 47 supplies the stored ionic liquid to the temperature regulating unit 48b via the pipe 46b. The temperature regulating unit 48 regulates the temperature of the ionic liquid supplied from the pipe 46b to predetermined temperature and supplies the ionic liquid to the pipe 46a. The ionic liquid supplied to the pipe 46a is dropped from the nozzle 55 to the placing surface 41a. In the configuration of the substrate processing apparatus 10 illustrated in FIG. 4, the pipes 46a and 46b, the supply unit 47, and the nozzle 55 correspond to the ionic liquid supply unit of the present disclosure. For example, the substrate processing apparatus 10 drops, from the nozzle 55, a certain liquid amount of the ionic liquid at which the film thickness of 2.6 mm or less is achieved on the placing surface 41a before the substrate W is placed on the placing surface 41a. With this configuration, the substrate processing apparatus 10 is able to form the film of the ionic liquid on the placing surface 41a, so that it is possible to stably hold the substrate W while preventing occurrence of a scratch on the back surface of the substrate W.

Furthermore, in one embodiment as described above, the example has been described in which, in the substrate processing apparatus 10, the ionic liquid is supplied to the surface of the electrostatic chuck 41. However, the disclosed technology is not limited to this example. For example, it may be possible to place the substrate W with the back surface on which a predetermined liquid amount of the ionic liquid is coated onto the placing surface 41a by the transfer mechanism. The ionic liquid is coated on the substrate W by an external different module, such as a transfer module that transfers the substrate W to the substrate processing apparatus 10. For example, the transfer module coats a certain liquid amount of the ionic liquid at which the film thickness reaches 2.6 mm or less on the back surface of the substrate W on the placing surface 41a, transfers the substrate W coated with the ionic liquid by the transfer mechanism, and places the substrate W on the placing surface 41a. The substrate processing apparatus 10 electrostatically adsorbs the substrate W placed on the placing surface 41a. Even in this case, the substrate processing apparatus 10 is able to stably hold the substrate W while preventing occurrence of a scratch on the back surface of the substrate W.

It should be understood that the exemplary embodiment disclosed herein is illustrative in all respects and is not restrictive. Indeed, the above exemplary embodiment may be embodied in various forms. The above exemplary embodiment may be omitted, replaced, or modified in various forms without departing from the scope and spirit of the appended claims.

In addition, regarding the above exemplary embodiment, the following supplementary notes are further disclosed.

According to an aspect of an embodiment, it is possible to prevent occurrence of a scratch on a substrate.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

In connection with the above embodiment, the following notes are further disclosed.

### (Note 1)

A substrate processing apparatus comprising:
a chamber;
an electrostatic chuck that is provided in the chamber, includes a placing surface for placing a substrate, and is able to electrostatically adsorb the substrate placed on the placing surface; and an ionic liquid supply unit that is able to supply an ionic liquid on the placing surface of the electrostatic chuck.

### (Note 2)

The substrate processing apparatus according to note 1, wherein the ionic liquid supply unit is configured to supply the ionic liquid so as to achieve a predetermined film thickness that allows electrostatic adsorption of the substrate on the placing surface.

### (Note 3)

The substrate processing apparatus according to note 2, wherein the ionic liquid supply unit supplies the ionic liquid so as to achieve a film thickness of 2.6 micrometers (μm) or less on the placing surface.

### (Note 4)

The substrate processing apparatus according to any one of notes 1 to 3, wherein the ionic liquid supply unit supplies the ionic liquid so as to maintain a state in which a film of the ionic liquid covers the placing surface.

### (Note 5)

The substrate processing apparatus according to any one of notes 1 to 4, wherein a flow-out port through which the ionic liquid supplied from the ionic liquid supply unit flows out is formed in the placing surface of the electrostatic chuck.

### (Note 6)

The substrate processing apparatus according to any one of notes 1 to 4, wherein a nozzle for dropping the ionic liquid supplied from the ionic liquid supply unit is provided in the chamber above the placing surface.

### (Note 7)

The substrate processing apparatus according to any one of notes 1 to 6, further comprising:
a recovery unit that recovers the ionic liquid around the electrostatic chuck, wherein
the ionic liquid supply unit supplies the ionic liquid that is recovered by the recovery unit.

### (Note 8)

The substrate processing apparatus according to any one of notes 1 to 7, further comprising:
a temperature regulating unit that regulates temperature of the ionic liquid, wherein
the ionic liquid supply unit supplies the ionic liquid for which the temperature is regulated by the temperature regulating unit.

### (Note 9)

The substrate processing apparatus according to any one of notes 1 to 8, wherein the ionic liquid exhibits viscosity of 120 mPa/s or less and has electrical conductivity of 2.6 mS/cm or less at 20° C.

### (Note 10)

The substrate processing apparatus according to any one of notes 1 to 9, wherein the ionic liquid consists of DEME (N,N-Diethly-N-methyl-N-(2-methoxyethyl)ammonium) as positive ions and TFSA⁻ (bis(trifluoromethanesulfonyl)imide) as negative ions.

### (Note 11)

A substrate holding method of a substrate processing apparatus including:
an electrostatic chuck that is provided in a chamber, includes a placing surface for placing a substrate, and is able to electrostatically adsorb the substrate placed on the placing surface; and
an ionic liquid supply unit that is able to supply an ionic liquid on the placing surface of the electrostatic chuck,
the substrate holding method comprising:
placing the substrate on the placing surface; and
supplying an ionic liquid from the ionic liquid supply unit to the placing surface while electrostatically adsorbing the substrate placed on the placing surface by the electrostatic chuck.

### (Note 12)

A substrate holding method of a substrate processing apparatus including:
an electrostatic chuck that is provided in a chamber, includes a placing surface for placing a substrate, and is able to electrostatically adsorb the substrate placed on the placing surface,
the substrate holding method comprising:
placing the substrate with a back surface coated with an ionic liquid on the placing surface; and
electrostatically adsorbing the substrate placed on the placing surface.

What is claimed is:

1. A substrate processing apparatus comprising:
a chamber;
an electrostatic chuck that is provided in the chamber, includes a placing surface for placing a substrate, and is able to electrostatically adsorb the substrate placed on the placing surface; and
an ionic liquid supply unit that is able to supply an ionic liquid on the placing surface of the electrostatic chuck.

2. The substrate processing apparatus according to claim 1, wherein the ionic liquid supply unit is configured to supply the ionic liquid so as to achieve a predetermined film thickness that allows electrostatic adsorption of the substrate on the placing surface.

3. The substrate processing apparatus according to claim 2, wherein the ionic liquid supply unit supplies the ionic liquid so as to achieve a film thickness of 2.6 micrometers (μm) or less on the placing surface.

4. The substrate processing apparatus according to claim 1, wherein the ionic liquid supply unit supplies the ionic liquid so as to maintain a state in which a film of the ionic liquid covers the placing surface.

5. The substrate processing apparatus according to claim 1, wherein a flow-out port through which the ionic liquid supplied from the ionic liquid supply unit flows out is formed in the placing surface of the electrostatic chuck.

6. The substrate processing apparatus according to claim 1, wherein a nozzle for dropping the ionic liquid supplied from the ionic liquid supply unit is provided in the chamber above the placing surface.

7. The substrate processing apparatus according to claim 1, further comprising:
a recovery unit that recovers the ionic liquid around the electrostatic chuck, wherein
the ionic liquid supply unit supplies the ionic liquid that is recovered by the recovery unit.

8. The substrate processing apparatus according to claim 1, further comprising:
a temperature regulating unit that regulates temperature of the ionic liquid, wherein
the ionic liquid supply unit supplies the ionic liquid for which the temperature is regulated by the temperature regulating unit.

9. The substrate processing apparatus according to claim 1, wherein the ionic liquid exhibits viscosity of 120 mPa/s or less and has electrical conductivity of 2.6 mS/cm or less at 20° C.

10. The substrate processing apparatus according to claim 1, wherein the ionic liquid consists of DEME (N,N-Diethly-N-methyl-N-(2-methoxyethyl)ammonium) as positive ions and TFSA⁻ (bis(trifluoromethanesulfonyl)imide) as negative ions.

11. A substrate holding method of a substrate processing apparatus including:
an electrostatic chuck that is provided in a chamber, includes a placing surface for placing a substrate, and is able to electrostatically adsorb the substrate placed on the placing surface; and
an ionic liquid supply unit that is able to supply an ionic liquid on the placing surface of the electrostatic chuck,
the substrate holding method comprising:
placing the substrate on the placing surface; and
supplying an ionic liquid from the ionic liquid supply unit to the placing surface while electrostatically adsorbing the substrate placed on the placing surface by the electrostatic chuck.

12. A substrate holding method of a substrate processing apparatus including:
an electrostatic chuck that is provided in a chamber, includes a placing surface for placing a substrate, and is able to electrostatically adsorb the substrate placed on the placing surface,
the substrate holding method comprising:
placing the substrate with a back surface coated with an ionic liquid on the placing surface; and
electrostatically adsorbing the substrate placed on the placing surface.
